(19) United States
(12) Patent Application Publication
(10) Pub. No.: US 2012/0225207 A1
(43) Pub. Date: Sep. 6, 2012

(54) Apparatus and Process for Atomic Layer Deposition

(75) Inventor: Joseph Yudovsky, Campbell, CA (US)

(73) Assignee: Applied Materials, Inc., Santa Clara, CA (US)

(21) Appl. No.: 13/037,572

(22) Filed: Mar. 1, 2011

(51) Int. Cl. C23C 16/458; C23C 16/44; C23C 16/455

(52) U.S. Cl. 427/255.5; 118/729; 118/724; 118/730; 427/248.1

(57) ABSTRACT

Provided is a substrate processing apparatus, such as an atomic layer deposition (ALD) chamber, comprising a substrate support on a swinging support arm and, optionally, a plurality of exhaust ducts located adjacent to but a distance from the gas distribution plate. One or more of the substrate processing apparatus may be a component of an integrated cluster tool to process multiple substrates concurrently.

### BACKGROUND

Embodiments of the invention generally relate to an apparatus and a method for depositing materials. More specifically, embodiments of the invention are directed to atomic layer deposition apparatus using reciprocal circular motion and cluster tools incorporating such apparatus.

In the field of semiconductor processing, flat-panel display processing or other electronic device processing, vapor deposition processes have played an important role in depositing materials on substrates.

During conventional atomic layer deposition (ALD) process, reactant gases are sequentially introduced into a process chamber containing a substrate. Generally, a first reactant is introduced into a process chamber and is adsorbed onto the substrate surface. A second reactant is then introduced into the process chamber and reacts with the first reactant to form a deposited material. A purge step may be carried out between the delivery of each reactant gas to ensure that the only reactions that occur are on the substrate surface. The purge step may be a continuous purge with a carrier gas or a pulse purge between the delivery of the reactant gases. This process is repeated to form layers having an overall desired thickness.

Layers of reactants may be applied using reciprocal linear motion techniques, whereby the gas streams are in constant contact with a surface of a substrate or a substrate carrier. The gas streams constant contact with a surface thereby only necessitates an exhaust above the substrate. Exhaust of the reactants is important in order to maintain complete control over the thickness of the layers of reactants.

Atomic layer deposition chambers using linear motion occupy significant amounts of space, making the size of cluster tools excessive. Therefore, there is an ongoing need in the art for apparatus and methods of reducing the size of the ALD apparatuses and cluster tools.

### SUMMARY

One or more embodiments of the invention are directed to substrate processing apparatus comprising a processing chamber with a gas distribution plate. The gas distribution plate comprises a plurality of gas ports and a plurality of vacuum ports. Each of the plurality of gas ports is configured to transmit a gas stream into the processing chamber. The plurality of vacuum ports are located between each gas port and are configured to transmit the gas streams out of the processing chamber. A substrate carrier is connected to a swinging support arm to move the substrate carrier in an arc adjacent the gas stream from the gas distribution plate.

In some embodiments, the swinging support arm moves the substrate carrier from a loading region, to a gas deposition region adjacent the gas distribution plate and to a non-deposition region away from the gas distribution plate. In one or more embodiments, the substrate carrier includes a thermal element for changing substrate temperature. In detailed embodiments, the substrate carrier is adapted to rotate a substrate. In specific embodiments, the rotation of the substrate carrier is continuous or the substrate carrier rotates in discrete steps when the substrate is in one or more of loading region or the non deposition region.

In detailed embodiments, the gas distribution plate and gas ports are wedge shaped in a radial direction so that when the substrate carrier passes the gas distribution plate and gas ports, a point on an outer edge of the substrate has substantially the same residence time under the gas ports as a point on an inner edge of the substrate.

In some embodiments, the processing chamber further comprises a stationary plate spaced from the gas distribution plate, such that the substrate carrier moves between the gas distribution plate and the stationary plate,

In one or more embodiments, the processing chamber further comprises a first process gas source in flow communication with one or more of the gas ports and a second process gas source different from the first process gas source in flow communication with one or more of the gas ports. The first process gas ports and second process gas ports are separated by at least one vacuum port. Detailed embodiments further comprise a plurality of exhaust ducts spaced from the gas distribution plate. The plurality of exhaust ducts include at least one first exhaust duct and at least one second exhaust duct, the at least one first exhaust duct positioned to collect gas from the at least one first process gas port and the at least one second exhaust duct positioned to collect gas from the at least one second process gas port when there is no substrate positioned between the gas distribution plate and the exhaust ducts.

Additional embodiments of the invention are directed to integrated cluster tools comprising a central transfer chamber and at least one substrate processing apparatus as described. In detailed embodiments, the central transfer chamber includes at least one robot configured to transfer a substrate to and from the support arm of the substrate processing apparatus.

Further embodiments of the invention are directed to methods of processing a substrate. A substrate is moved on a substrate carrier in an arc from loading region deposition region adjacent he gas distribution plate so that a top surface of the substrate passes beneath the gas distribution plate. The substrate is sequentially exposed to a first reactive process gas from a first gas port in the gas distribution plate and a second reactive process gas from a second gas port in the gas distribution plate. The first gas port is in flow communication with a first process gas and the second gas port in flow communication with a second process gas different from the first process gas.

Detailed embodiments further comprise positioning the substrate on the substrate carrier when the substrate carrier is in loading region. In specific embodiments, the substrate is moved on the carrier from a loading region, to a deposition region, and to a non-deposition region away from the gas distribution plate repeatedly in order.

In one or more embodiments, the temperature of the substrate is changed using a thermal element in the substrate carrier.

In some embodiments, the substrate is rotated continuously during processing. In one or more embodiments, the substrate is rotated in discrete steps when the substrate is in one or more of the loading region and the non-deposition region away from the gas distribution plate.

Specific embodiments of the invention further comprise collecting the first reactive process gas in a first exhaust duct and the second reactive process gas in a second exhaust duct when the substrate carrier is in one or more of the region before the gas distribution plate and the region after the gas distribution plate.

Additional embodiments of the invention are directed to methods of forming a film on a substrate. A substrate is swung on a swinging substrate carrier in an arcuate path adjacent to a plurality of gas deposition channels to sequentially expose the substrate to at least two different reactive gases to form the film on the substrate by an atomic layer deposition process.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic cross-sectional side view of an atomic layer deposition chamber according to one or more embodiments of the invention;

FIG. 2 shows a schematic top view of a processing chamber in accordance with one or more embodiments;.

FIG. 3 shows a gas distribution plate in accordance with one or more embodiments of the invention;

FIGS. 4A-4C shows a side view of a processing chamber in accordance with one or more embodiments of the invention;

FIG. 5 shows a cluster tool comprising multiple substrate processing apparatus in accordance with one or more embodiments of the invention; and

FIG. 6 shows a schematic cross-sectional side view of an atomic layer deposition chamber according to one or more embodiments of the invention.

### DETAILED DESCRIPTION

Embodiments of the invention are directed to a substrate processing apparatus to allow atomic layer deposition (ALD). Other embodiments of the invention are directed to a cluster tool to be used in conjunction with one or more substrate processing apparatus, and also to a method of processing a substrate using a substrate processing apparatus.

To integrate short stroke atomic layer deposition (SS-ALD) chambers on a platform with other or identical chambers, use of a swinging arm is described. The chamber with a swinging arm could have a smaller footprint than a chamber with a reciprocal linear motion. This arm will move a substrate on a substrate carrier under an SSALD type injector. The injector will provide one or more ALD sequences. The slots in the injectors may be wedge shaped in a radial direction to provide the same residence time for the inner and the outer radii of the substrate on the arm.

The substrate carrier (heater) has a size which does not significantly exceed that of a substrate. When a substrate and the carrier are out of the injector and they do not cover the injector slots, the precursors and purge gases escape into the pumping slots in the injector and to the exhaust ducts under the carrier. Two exhaust ducts provide the separate exhausts for the different precursors.

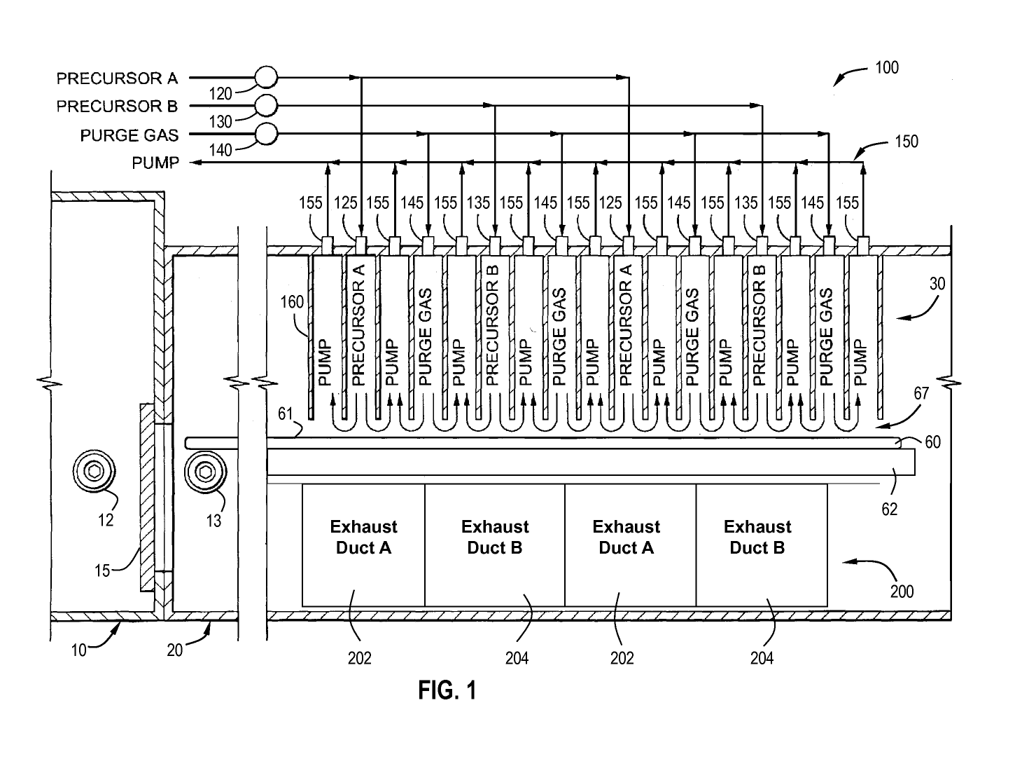

FIG. 1 is a schematic cross-sectional side view of an atomic layer deposition system 100 in accordance with one or more embodiments of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position. In one or more embodiments, substrate 60 is a rigid, generally planar substrate, for example, a semiconductor substrate, such as a 200 mm or 300 mm diameter semiconductor substrate.

The system 100 further includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The gas distribution plate 30 faces the top surface 61 of the substrate 60.

The gas distribution plate 30 of some embodiments comprises a plurality of gas ports configured to transmit one or more gas streams to the substrate 60 and a plurality of vacuum ports disposed between each gas port and configured to transmit the gas streams out of the processing chamber 20. The gas ports being in flow communication with a plurality of process sources, where the process sources may include purge gases and precursor gases.

In the detailed embodiment of FIG. 1, the gas distribution plate 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 is configured to inject a continuous (or pulse) stream of a reactive precursor of compound A into the processing chamber 20 through a plurality of gas ports 125. The precursor injector 130 is configured to inject a continuous (or pulse) stream of a reactive precursor of compound B into the processing chamber 20 through a plurality of gas ports 135. The purge gas injector 140 is configured to inject a continuous (or pulse) stream of a non-reactive or purge gas into the processing chamber 20 through a plurality of gas ports 145. The purge gas is configured to remove reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and/or the precursor injector 130 prior to injecting the precursors into the chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 when the substrate is beneath the gas distribution plate 30, after the gas streams react with the substrate surface and to further limit cross-contamination between the precursors.

The system 100 shown in FIG. 1 includes a plurality of partitions 160 disposed on the processing chamber 20 between each port. A lower portion of each partition extends close to substrate 60, for example about 0.5 mm from the substrate surface. In this manner, the lower portions of the partitions 160 are separated from the substrate surface by a distance sufficient to allow the gas streams to flow around the lower portions toward the vacuum ports 155 after the gas streams react with the substrate surface. Arrows indicate the direction of the gas streams when a substrate is beneath the gas distribution plate. Since the partitions 160 operate as a physical barrier to the gas streams, they also limit cross-contamination between the precursors. The arrangement shown in FIG. 1 is merely illustrative and should not be taken as limiting the scope of the invention. It will be understood by those skilled in the art that the gas distribution system shown in FIG. 1 is merely one possible distribution system and the other types of showerheads may be employed.

In operation, substrate 60 is delivered (e.g., by a robot) to the load lock chamber 10 and is placed on a system capable of moving the substrate 60. The system capable of moving the substrate 60 shown in FIG. 1 is a roller 12, but other mechanisms may be used. The isolation valve 15 is opened to allow the substrate 60 to be disposed in the processing chamber 20. The roller 13 may be helpful in transitioning the substrate 60 from the load lock chamber 10 to the processing chamber 20, but is not necessary. The substrate 60, which has a top surface 61 and a bottom surface is adjacent the gas distribution plate 70. A process gap 67 is defined between the top surface 61 of the substrate 60 and the gas distribution plate 30.

As the substrate 60 moves through the processing chamber 20, a surface of substrate 60 is repeatedly exposed to the precursor of compound A coming from gas ports 125 and the precursor of compound B coming from gas ports 135, with the purge gas coming from gas ports 145 in between. Injection of the purge gas is designed to remove unreacted material from the previous precursor prior to exposing the surface of the substrate 60 to the next precursor.

After each exposure to the various gas streams (e.g., the precursors or the purge gas), the gas streams are evacuated through the vacuum ports 155 by the pumping system 150 when the substrate is beneath the gas distribution plate 30. Since a vacuum port 155 may be disposed on both sides of each gas port, the gas streams are evacuated through the vacuum ports 155 on both sides when the substrate is directly beneath the gas distribution plate. Thus, the gas streams flow from the respective gas ports vertically downward toward the surface of the substrate 60, across the surface of the substrate 60 and around the lower portions of the partitions 160, and finally upward toward the vacuum ports 155. In this manner, each gas may be uniformly distributed across the surface of the substrate 60. Arrows indicate the direction of the gas flow. Substrate 60 may also be rotated while being exposed to the various gas streams.

Sufficient space is generally provided at the end of the processing chamber 20 so as to ensure complete exposure by the last gas port in the processing chamber 20. Once the substrate 60 reaches an end of the processing chamber 20 (i.e., the surface of the substrate 60 has completely been exposed to every gas port in the chamber 20), the substrate 60 returns back in a direction toward the load lock chamber 10. As the substrate 60 moves back toward the load lock chamber 10, the substrate surface may be exposed again to the precursor of compound A, the purge gas, and the precursor of compound B, in reverse order from the first exposure.

The extent to which the surface of the substrate 60 is exposed to each gas may be determined by, for example, the flow rates of each gas coming out of the gas port and the rate of movement of the substrate 60. In one embodiment, the flow rates of each gas are configured so as not to remove absorbed precursors from the surface of the substrate 60. The width between each partition, the number of gas ports disposed on the processing chamber 20, and the number of times the substrate is passed back and forth may also determine the extent to which the surface of the substrate 60 is exposed to the various gases. Consequently, the quantity and quality of a deposited film may be optimized by varying the above-referenced factors.

In another embodiment, the system 100 may include a precursor injector 120 and a precursor injector 130, without a purge gas injector 140. Consequently, as the substrate 60 moves through the processing chamber 20, the surface of the substrate 60 will be alternately exposed to the precursor of compound A and the precursor of compound B, without being exposed to purge gas in between.

When the substrate 60 reaches the isolation valve 15, the isolation valve 15 opens so as to allow the substrate 60 to move through the isolation valve 15 to load lock chamber 10. The isolation valve 15 then closes to seal the processing chamber 20. Substrate 60 may be cooled by load lock chamber 10 prior to being retrieved by a robot for further processing.

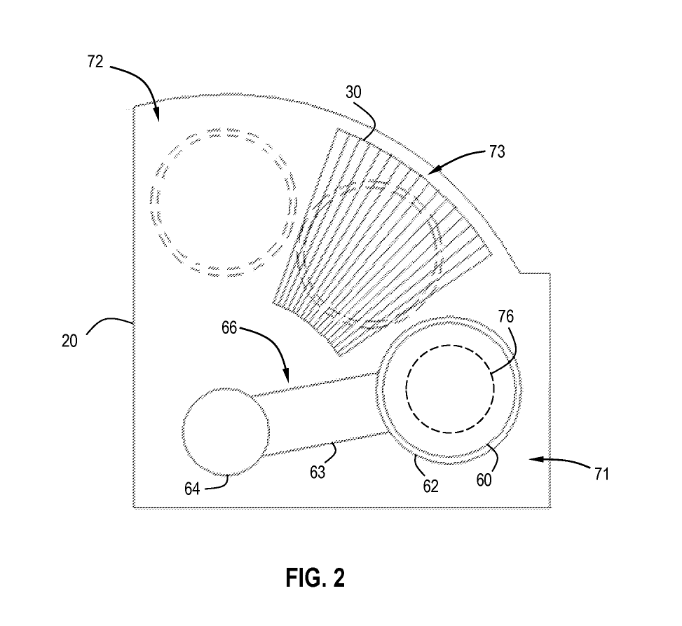

FIG. 2 shows another embodiments of a substrate processing apparatus. The processing chamber 20 shown has a gas distribution plate 30 within. The gas distribution plate 30 comprises a plurality of gas ports and vacuum ports. Each of which is configured to transmit a gas stream into the processing chamber 20 and each of the plurality of vacuum ports is configured to transmit gases out of the processing chamber 20. A swinging support arm 66 transports the substrate 60 on a substrate carrier 62 in an arc adjacent the gas streams from the gas distribution plate 30. The swinging support arm 66 moves the substrate carrier 62, and the substrate 60, back and forth from a loading region 71 through the gas deposition region 73 to a non-deposition region 72 away from the gas deposition region 73. The gas deposition region 73 is the area adjacent (e.g., under, over, next to) the gas distribution plate 30 toward which the flow of gases is directed. The swinging support arm 66 is connected to the substrate carrier 62 by a support arm 63 connected to a rotor 64.

The length of the support arm 63 from the center of the rotor 64 to the center of the substrate carrier 62 defines an operable radius. The operable radius may have an impact on the deposition as the longer the radius, the larger disparity between the velocity of a point on the inside of the substrate versus a point on the outside of the substrate relative to the gas distribution plate. In various embodiments, the operable radius is in the range of about 300 to about 700 mm, or in the range of about 350 to about 650 mm, or in the range of about 400 to about 600 mm, or in the range of about 450 to about 550 mm. In detailed embodiments, the operable radius is about 500 mm.

As seen in FIG. 2, the substrate carrier 62 is rotated on the end of the support arm 63. The substrate carrier 62 with a substrate 60 is shown in phantom along the route that the substrate will travel. For example, a phantom representation is shown beneath the gas distribution plate 30 and a second phantom representation is shown at the end of the travel path. The substrate carrier 62 of some embodiments is configured to transport a substrate 60 in an arc from a loading region 71 to a non-deposition region 72 after the gas distribution plate 30 (i.e., away from the deposition region 73). In regions 71 and 72, there is substantially no reactive processing gases contacting the surface of the substrate 60. As used in this specification and the appended claims, the term “substantially no reactive process gases” means that the reactive processing gases are not intentionally contacting the surface. It is possible that there are stray molecules of these gases escaping into the chamber which may contact the surface of the substrate.

The loading region 71 before the gas distribution plate 30 may serve as a useful point for loading and unloading the substrate from the substrate carrier 62. At this point, a load lock 10 may be connected, or a central transfer chamber of a cluster tool may make connection here. It is also possible for there to be a load lock 10 at the non-deposition region 72 after the gas distribution plate 30. This may allow for the substrate 60 to be loaded in loading region 71 before processing and unloaded in non-deposition region 72 after processing.

In some embodiments, the substrate carrier 62 includes a thermal element 76 for changing substrate temperature. The thermal element 76 can be used to increase the temperature or decrease the temperature of the substrate 60 and the substrate carrier 62. Increasing temperature can be done by any suitable thermal elements 76, including but not limited to, resistive heaters. Decreasing temperature can be done by any suitable thermal elements 76, including but not limited to, Peltier devices.

In detailed embodiments, the substrate carrier 62 is adapted to rotate the substrate 60. Rotation of the substrate can be continuous throughout some or all of the deposition process, or can be in discrete steps. In specific embodiments, the substrate 60 is rotated in discrete steeps of 10, 20, 30, 40, 50 or 60 degrees. Rotation of the substrate may be performed at any point during the transit from the loading region 71 to non-deposition region 72. However, it may be most useful if performed while the substrate is in loading region 71 or non-deposition region 72, rotating the substrate 60 when the substrate 60 is not under the gas distribution plate 30. This rotation helps create a more uniform deposited layer In detailed embodiments, the direction of rotation is opposite the direction that the arm will swing in. For example, if the arm will swing, initially, in a counter clockwise direction, then the substrate will be rotated clockwise.

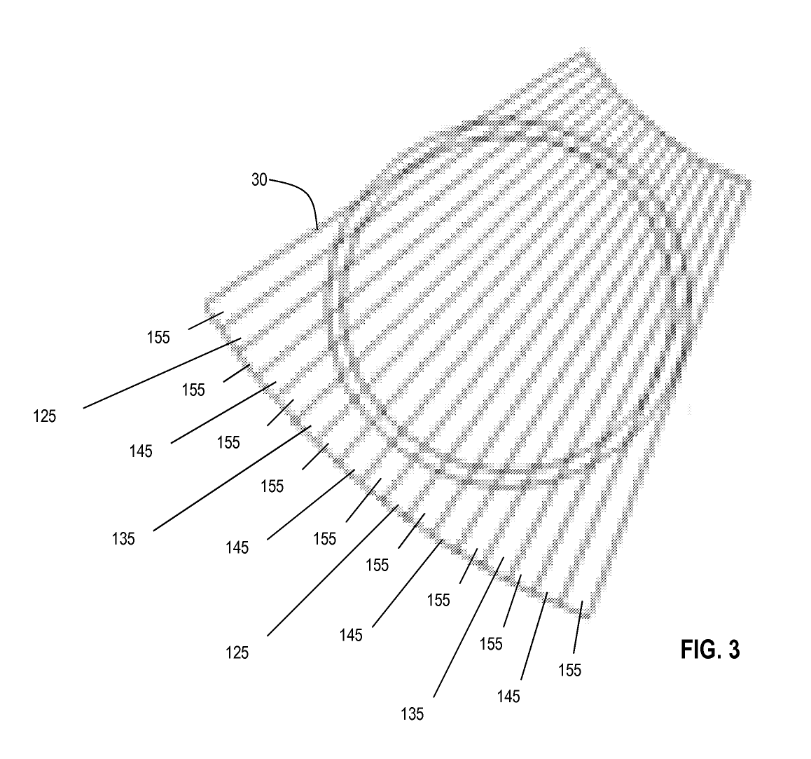

FIGS. 2 and 3 show embodiments of the invention in which the gas distribution plate 30 is wedge shaped. In these embodiments, the gas ports may also be wedge shaped. Wedge shaped gas ports may help in the deposition of a uniform film because all points of the substrate have approximately equal residence time under the gas ports. The substrate processing apparatus of claim 1, wherein the gas distribution plate and gas ports are wedge shaped in a radial direction so that when the substrate carrier passes the gas distribution plate and gas ports, a point on an outer edge of the substrate has substantially the same residence time under the gas ports as a point on an inner edge of the substrate (all points of the substrate have the same relative angular velocity with respect to the gas ports).

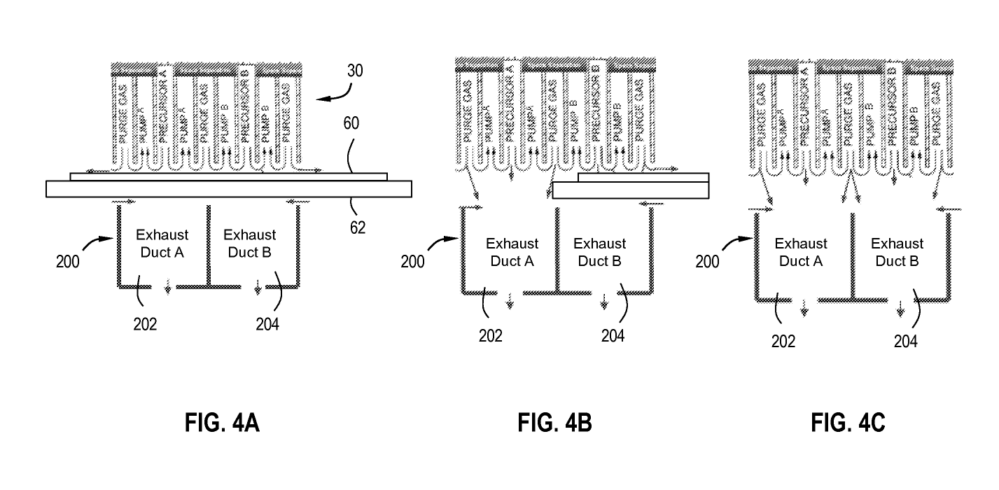

It can be seen from FIG. 2, that when the substrate 60 and substrate carrier 62 are not directly beneath the gas distribution plate 30, the gas streams can escape into the chamber as there is no surface to cause the gas flows to change direction and be removed by the vacuum ports. To avoid having the gases floating freely in the chamber, a plurality of exhaust ducts 200, as shown in FIGS. 1 and 4A-4C, are placed a distance from the gas distribution plate 30. The distance between the gas distribution plate 30 and the exhaust ducts 200 is sufficient to allow the substrate carrier 62 and the substrate 60 to pass between. However, minimizing this distance will further prevent gases from escaping. In various embodiments, the distance between the gas distribution plate 30 and the exhaust ducts 200 is less than about 15 mm, 14 mm, 13 mm, 12 mm, 11 mm, 10 mm, 9 mm, 8 mm, 7 mm, 6 mm or 5 mm. In various embodiments, the distance between the gas distribution plate 30 and the exhaust ducts 200 is in the range of about 5 mm to about 15 mm, or in the range of about 6 mm to about 14 mm, or in the range of about 7 mm to about 13 mm, or in the range of about 8 mm to about 12 mm or in the range of about 9 mm to about 11 mm. In detailed embodiments, the distance between the gas distribution plate 30 and the exhaust ducts 200 is about 10 mm. In various embodiments, the distance between the gas distribution plate 30 and the exhaust ducts 200 is less than about 10 mm, 9 mm, 8 mm, 7 mm, 6 mm, or 5 mm. In one or more embodiments, the distance between the gas distribution plate 30 and the exhaust ducts is about 5 mm.

In detailed embodiments, exhaust duct A 202 collects precursor A, and some purge gases from either side of precursor A and exhaust duct B 204 collects precursor B and some purge gases from either side of precursor B. There can be any number of repeating exhaust duct A 202 and exhaust duct B 204 ducts as there are precursor A ports 125 and precursor B ports 135. In specific embodiments, exhaust duct A 202 collects substantially none of precursor B, and exhaust duct B 204 collects substantially none of precursor A. As used in this specification and the appended claims, the term “substantially non of” when referring to the exhaust duct 200 collections means at least less than about 20% is collected, or less than about 10%, or less than about 5%.

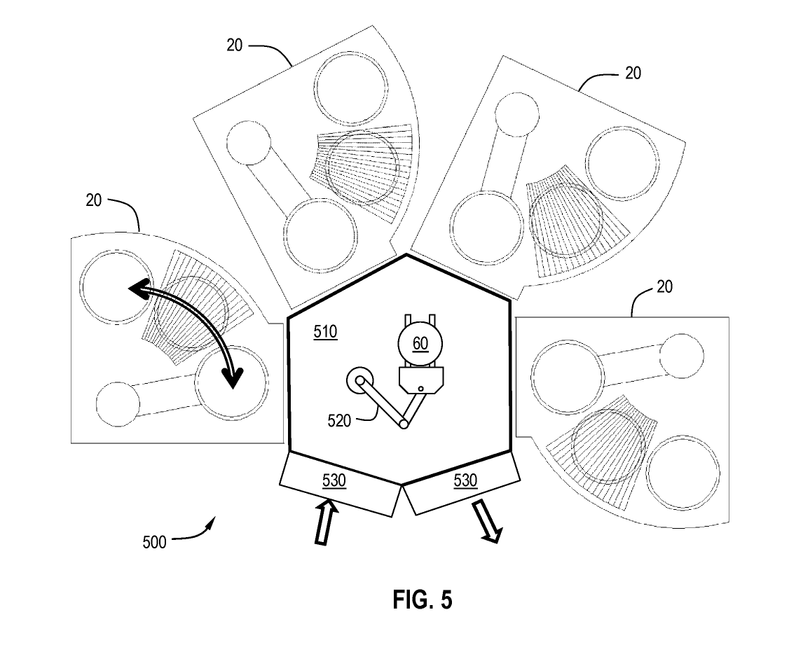

As shown in FIG. 5, the substrate processing apparatus may be used as part of an integrated cluster tool 500. Generally, a cluster tool 500 is a modular system comprising multiple chambers which perform various functions including substrate center-finding and orientation, degassing, annealing, deposition and/or etching. The integrated cluster tool 500 may be adapted to comprise a plurality of substrate processing apparatus in order to accommodate multiple concurrent substrate processes. The multiple chambers of the cluster tool are mounted to a central transfer chamber 510 which houses a robot 520 adapted to shuttle substrates 60 between the chambers 20. The central transfer chamber 510 is typically maintained at a vacuum condition and provides an intermediate stage for shuttling substrates 60 from one chamber 20 to another and/or to one or more load lock chambers 530 positioned at a front end of the cluster tool 500.

In yet another embodiment, the system 100 may be configured to process a plurality of substrates. In such an embodiment, the system 100 may include a second load lock chamber and a plurality of substrate 60. The substrates 60 may be delivered to the load lock chamber 10 and retrieved from the second load lock chamber.

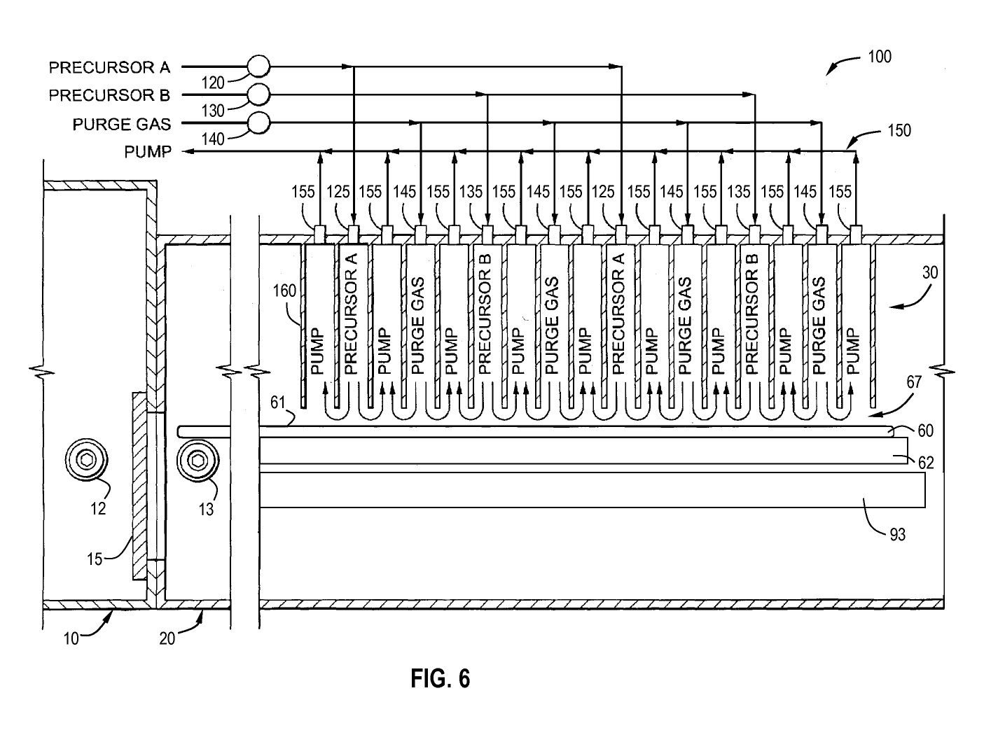

FIG. 6 shows another embodiment of the invention in which there are no exhaust ducts 200. In this embodiment, when the substrate 60 and substrate carrier 62 are out of the region adjacent the gas distribution plate 30 (the region where the gas streams come into contact with the substrate 60), a stationary plate 93 prevents gases from the gas distribution plate 30 from entering the processing chamber 20 bulk environment. The stationary plate 93 can prevent gases from escaping into the chamber if the gap between the gas distribution plate 30 and the stationary plate 93 is not too large. When the substrate 60 and substrate carrier 62 are not in the processing gap 67, gas flow from the gas ports 125, 135 and 145 are directed away from the gas distribution plate 30 where they encounter the surface of the stationary plate 93 and change flow in the same manner as described with respect to FIG. 1. Embodiments without the exhaust ducts make it possible to incorporate the swinging support arm 66 without dumping precursor into the processing chamber 20.

In various embodiments, the gap between the gas distribution plate 30 and the stationary plate 93 is less than about 10 mm, 9 mm, 8 mm, 7 mm, 6 mm, or 5 mm. In one or more embodiments, the gap between the gas distribution plate 30 and the stationary plate 93 is about 5 mm. In a specific embodiment, in which the substrate 60 is about 0.8 mm thick and the substrate carrier 62 is about 2-3 mm thick, the gap between the gas distribution plate 30 and the stationary plate 93 is in the range of about 6 mm to about 10 mm.

Additional embodiments of the invention are directed to methods of processing a substrate. Referring again to FIG. 2, a substrate 60 is moved on a substrate carrier 62 in an arc from a loading region 71 before a gas distribution plate 30 to a non-deposition region 72 after the gas distribution plate 30. The substrate 60 moves so that a top surface 61 of the substrate 60 passes beneath the gas distribution plate 30. The substrate 60 is sequentially exposed to a first reactive process gas from a first gas port in the gas distribution plate 30 and a second reactive process gas from a second gas port in the gas distribution plate 30. As used in this specification and the appended claims, the term “reactive gas” means a gas that will react with either the substrate, the surface of the substrate or a compound on the surface of the substrate. Purge gases (e.g., nitrogen and argon) are not reactive, generally, and are not considered reactive gases. The first gas port is in flow communication with a first process gas and the second gas port is in flow communication with the second process gas different from the first process gas. Some embodiments further comprise collecting the first reactive process gas in a first exhaust duct 202 and the second reactive process gas in a second exhaust duct 204 when the substrate carrier 62 is in one or more of the loading region 71 before the gas distribution plate 30 and the non-deposition region 72 after the gas distribution plate 30.

Detailed embodiments further comprise positioning the substrate 60 on the substrate carrier 62. The substrate 60 can be positioned on the substrate carrier 62 when the substrate carrier 62 is in the loading region 71 before the gas distribution plate 30. Additionally, the substrate 60 can be positioned on the substrate carrier 62 when the substrate carrier 62 is in the non-deposition region 72 after the gas distribution plate 30 or anywhere in between loading region 71 and non-deposition region 72.

In various embodiments, the substrate 60 temperature is changed using a thermal element 76 in the substrate carrier 62. The substrate 60 may also be rotated on the substrate carrier 62, either by rotating the substrate carrier or just the substrate 60. The rotation can be continuous or in discrete steps as described above.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

1. A substrate processing apparatus comprising:
a processing chamber;
a gas distribution plate in the processing chamber comprising a plurality of gas ports and a plurality of vacuum ports, each of the plurality of gas ports transmit a gas stream into the processing chamber, the plurality of vacuum ports located between each gas port transmit the gas streams out of the processing chamber; and
a substrate carrier connected to a swinging support arm that moves the substrate carrier in an arc adjacent the gas stream from the gas distribution plate.

2. The substrate processing apparatus of claim 1, wherein the swinging support arm moves the substrate carrier from a loading region to a gas deposition region adjacent the gas distribution plate and to a non-deposition region away from the gas distribution plate.

3. The substrate processing apparatus of claim 1, wherein the substrate carrier includes a thermal element that changes substrate temperature.

4. The substrate processing apparatus of claims 1, wherein the substrate carrier rotates a substrate.

5. The substrate processing apparatus of claim 4, wherein the rotation is continuous.

6. The substrate processing apparatus of claim 4, wherein the substrate carrier rotates in discrete steps when the substrate is in one or more of loading region or the non deposition region.

7. The substrate processing apparatus of claim 1, wherein the gas distribution plate and gas ports are wedge shaped in a radial direction so that when the substrate carrier passes the gas distribution plate and gas ports, a point on an outer edge of the substrate has substantially the same residence time under the gas ports as a point on an inner edge of the substrate.

8. The substrate processing apparatus of claim 1, further comprising a stationary plate spaced from the gas distribution plate such that the substrate carrier moves between the gas distribution plate and the stationary plate.

9. The substrate processing apparatus of claim 1, further comprising a first process gas source in flow communication with one or more of the gas ports and a second process gas source different from the first process gas source in flow communication with one or more of the gas ports, the first process gas ports and second process gas ports separated by at least one vacuum port.

10. The substrate processing apparatus of claim 8, further comprising a plurality of exhaust ducts spaced from the gas distribution plate, the plurality of exhaust ducts include at least one first exhaust duct and at least one second exhaust duct, the at least one first exhaust duct collects gas from the at least one first process gas port and the at least one second exhaust duct collects gas from the at least one second process gas port when there is no substrate positioned between the gas distribution plate and the exhaust ducts.

11. An integrated cluster tool comprising a central transfer chamber and at least one substrate processing apparatus of claim 1.

12. The integrated cluster tool of claim 11, wherein the central transfer chamber includes at least one robot that transfers a substrate to and from the support arm of the substrate processing apparatus.

13. A method of processing a substrate, comprising:
moving a substrate on a substrate carrier in an arc from loading region deposition region adjacent he gas distribution plate so that a top surface of the substrate passes beneath the gas distribution plate; and
sequentially exposing the substrate to a first reactive process gas from a first gas port in the gas distribution plate, the first gas port in flow communication with a first process gas and a second reactive process gas from a second gas port in the gas distribution plate, the second gas port in flow communication with a second process gas different from the first process gas.

14. The method of claim 13, further comprising positioning the substrate on the substrate carrier when the substrate carrier is in loading region.

15. The method of claim 14, wherein the substrate is moved on the carrier from a loading region, to a deposition region, and to a non-deposition region away from the gas distribution plate repeatedly in order.

16. The method of claim 14, further comprising changing temperature of the substrate using a thermal element in the substrate carrier.

17. The method of claim 14, further comprising rotating the substrate continuously during processing.

18. The method of claim 15, further comprising rotating the substrate in discrete steps when the substrate is in one or more of the loading region and the non-deposition region away from the gas distribution plate.

19. The method of claim 13, further comprising collecting the first reactive process gas in a first exhaust duct and the second reactive process gas in a second exhaust duct when the substrate carrier is in one or more of the region before the gas distribution plate and the region after the gas distribution plate.

20. A method of forming a film on a substrate comprising:
swinging a substrate on a substrate carrier in an arcuate path adjacent a plurality of gas deposition channels to sequentially expose the substrate to at least two different reactive gases to form the film on the substrate by an atomic layer deposition process.
